(19) United States
(12) Patent Application Publication
(10) Pub. No.: US 2021/0384370 A1
(43) Pub. Date: Dec. 9, 2021

(54) THIN-FILM SOLAR CELL

(71) Applicant: HSUN-TIEN HOU, Chiayi County (TW)

(72) Inventor: HSUN-TIEN HOU, Chiayi County (TW)

(21) Appl. No.: 16/894,581

(22) Filed: Jun. 5, 2020

(51) Int. Cl. H01L 31/0465; H01L 31/0224; H01L 31/0463; H01L 31/054; H01L 31/073; H01L 31/0749

(52) U.S. Cl. CPC H01L 31/0465; H01L 31/022466; H01L 31/022475; H01L 31/0749; H01L 31/0463; H01L 31/0543; H01L 31/073; H01L 31/022483

(57) ABSTRACT

A thin-film solar cell contains: a lens material layer, a conductive contact layer, a first n-p semiconductor layer, a second n-p semiconductor layer, an insulation layer, a transparent conducting layer, a substrate, multiple first vias, multiple insulators, and multiple electrical conductors. A respective first via passes through the lens material layer, the conductive contact layer, and the first n-p semiconductor layer. The multiple insulators are accommodated in the respective first via, a top of a respective insulator is connected with the second n-p semiconductor layer, and a bottom of the respective insulator is connected with the insulation layer. The respective insulator includes a respective second via. A respective electrical conductor is formed in the respective second via, a top of the respective electrical conductor is connected with a respective transparent conducting layer, and a bottom of the respective electrical conductor is connected with the substrate.

### FIELD OF THE INVENTION

The present invention relates to a thin-film solar cell, and more particularly to the thin-film solar cell which has multiple-vias conducting paths.

### BACKGROUND OF THE INVENTION

A solar cell (such as a thin-film solar cell) is compact because of its material, but a photoelectric conversion efficiency of the solar cell is quite low, thus increasing the photoelectric conversion efficiency is inevitable.

A conventional thin-file solar cell, such as p-i-n type silicon thin-film solar cell disclosed in TW Publication Nos. 201140860 and 201032332 is produced delicately, so providing a plane glass substrate is required. However, the plane glass substrate is broken easily in strong wind, heavy rain or waves and is manufactured at high cost. Furthermore, the glass substrate is manufactured troublesomely and is not flexible enough to mate with a curved portion of an installation site.

To overcome above-mentioned defects, an improved thin-film solar cell is disclosed in TW Publication No. 201916393, wherein the thin-film solar cell contains conductive material made of stainless steel foil to obtain flexibility, to mate with the curved portion of the installation site, and to avoid fragile damage. Nevertheless, the thin-film solar cell is only applicable for amorphous silicon thin film semiconductor mating with aluminum, yet aluminum cannot match with other semiconductors, thus limiting applications.

The present invention has arisen to mitigate and/or obviate the afore-described disadvantages.

### SUMMARY OF THE INVENTION

The primary objective of the present invention is to provide a thin-film solar cell which is flexible and is applicable for curved portions of an installation site.

Another objective of the present invention is to provide a thin-film solar cell which contains a conductive contact layer made of a material mating with a material of the first n-p semiconductor layer, thus increasing material options.

To obtain above-mentioned objectives, a thin-film solar cell provided by the present invention contains: a lens material layer, a conductive contact layer, a first n-p semiconductor layer, a second n-p semiconductor layer, an insulation layer, a transparent conducting layer, a substrate, multiple first vias, multiple insulators, and multiple electrical conductors.

The conductive contact layer is stacked on the lens material layer. The first n-p semiconductor layer is stacked on the conductive contact layer. The second n-p semiconductor layer is stacked on a top of the first n-p semiconductor layer. The insulation layer is stacked on a bottom of the lens material layer. The transparent conducting layer is stacked on a top of the second n-p semiconductor layer. The substrate is stacked on a bottom of the insulation layer. A respective of the multiple first via passes through the lens material layer, the conductive contact layer, and the first n-p semiconductor layer. The multiple insulators are accommodated in the respective first via, a top of a respective insulator is connected with the second n-p semiconductor layer, and a bottom of the respective insulator is connected with the insulation layer. The respective insulator includes a respective of multiple second vias. A respective electrical conductor is formed in the respective second via, a top of the respective electrical conductor is connected with a respective transparent conducting layer of at least one transparent conducting layer, and a bottom of the respective electrical conductor is connected with the substrate.

Preferably, the transparent conducting layer includes a first part and a second part, the first part is stacked on the second n-p semiconductor layer in a sputter deposition manner or an evaporation manner, the second part is staked on the first part in a chemical bath deposition (CBD) manner, thus producing the respective electrical conductor.

Preferably, the first n-p semiconductor layer is p-type semiconductor material made of copper indium gallium selenite (CIGS), and the conductive contact layer is made of molybdenum (Mo), wherein the second n-p semiconductor layer is n-type semiconductor material, and the n-type semiconductor material is cadmium sulfide (CdS).

Preferably, the first n-p semiconductor layer is p-type semiconductor material made of cadmium telluride (CdTe), and the conductive contact layer is made of carbon or tin oxide, wherein the second n-p semiconductor layer is n-type semiconductor material, and the n-type semiconductor material is cadmium sulfide (CdS).

Preferably, the insulation layer and the respective insulator are made of materials the same as a martial of the second n-p semiconductor layer.

Preferably, the materials of the second n-p semiconductor layer, the respective insulator, and the insulation layer are cadmium sulfide (CdS).

Preferably, the first n-p semiconductor layer, the conductive contact layer, and the lens material layer are insulated by an insulating edge.

Preferably, the lens material layer is made of conductive material or non-conductive material.

Preferably, the lens material layer is selected from any one of plastic, stone paper, and stainless steel.

Preferably, the transparent conducting layer is made of a material selected from any one of zinc oxide (ZnO), indium tin oxide (ITO), fluorine-doped tin oxide (FTO), antimony tin oxide (ATO), iridium tin oxide film (IRTOF), and tin oxide (SnO₂).

Preferably, a material of the transparent conducting layer is zinc oxide (ZnO), the respective second via extends to and passes through the transparent conducting layer, and the respective electrical conductor is filled in the respective second via, wherein the respective electrical conductor is silver glue.

### BRIEF DESCRIPTION OF THE DRAWINGS

FIG. 1 is a perspective view showing the assembly of a thin-film solar cell according to a preferred embodiment of the present invention.

FIG. 2A is a cross sectional view taken along the line 2A-2A of FIG. 1.

FIG. 2B is a cross sectional view taken along the line 2B-2B of FIG. 1.

FIGS. 3a to 3f are a cross sectional view showing steps of manufacturing the thin-film solar cell according to the preferred embodiment of the present invention.

FIG. 4 is a cross section view showing the assembly of a thin-film solar cell according to another preferred embodiment of the present invention.

FIG. 5 is a cross section view showing the assembly of a thin-film solar cell according to another preferred embodiment of the present invention.

FIG. 6 is a cross section view showing the assembly of a thin-film solar cell according to another preferred embodiment of the present invention.

FIG. 7 is a cross section view showing the assembly of a thin-film solar cell according to another preferred embodiment of the present invention.

### DETAILED DESCRIPTION OF THE PREFERRED EMBODIMENTS

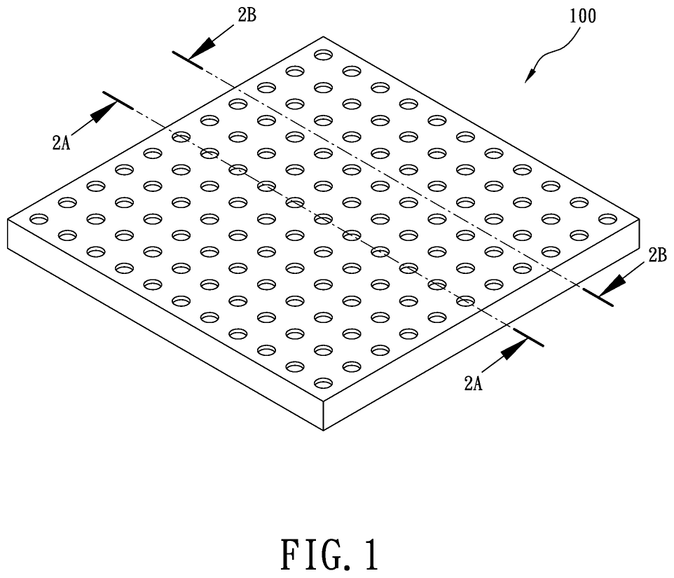

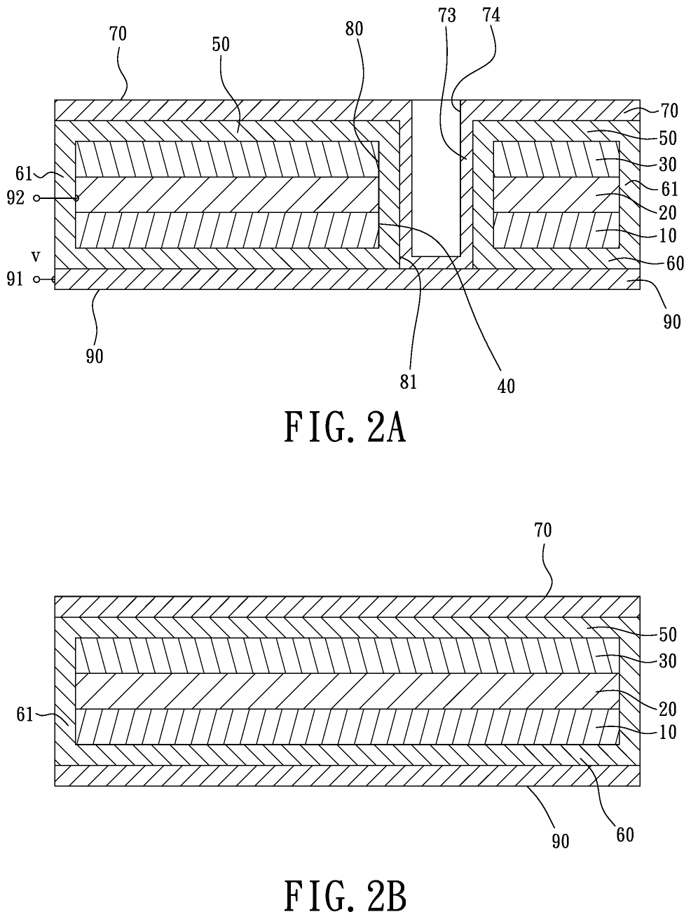

With reference to FIG. 1, a thin-film solar cell according to a preferred embodiment of the present invention comprises: multiple first vias 40. To simplify the thin-film solar cell, only one first via 40 is shown in FIGS. 2 to 7. Referring to FIGS. 1, 2A, and 2B, the thin-film solar cell 100 according to the preferred embodiment of the present invention comprises: a lens material layer 10, a conductive contact layer 20, a first n-p semiconductor layer 30, the multiple first vias 40, a second n-p semiconductor layer 50, an insulation layer 60, multiple insulators 80, a transparent conducting layer 70, a substrate 90, and multiple electrical conductors 73.

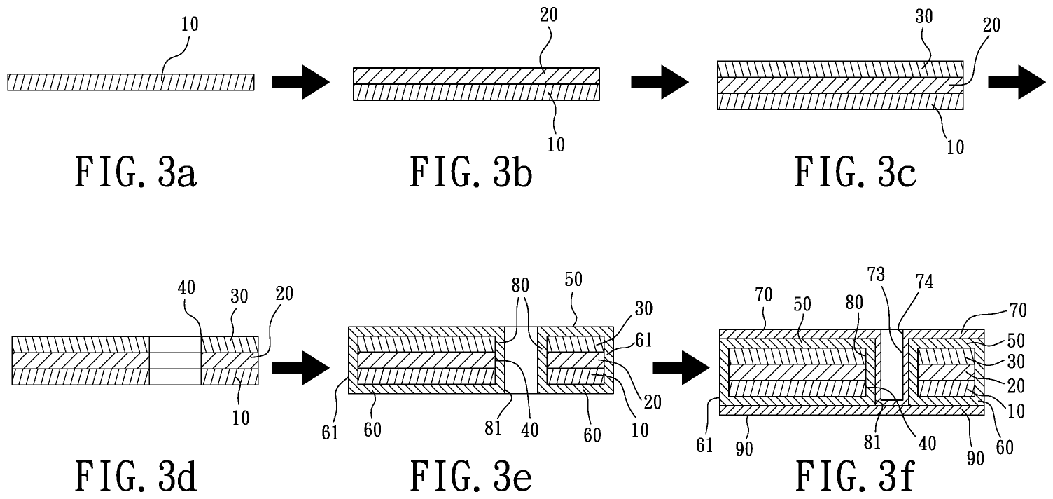

FIGS. 3a-3f are a cross sectional view showing steps of manufacturing the thin-film solar cell 100 according to the preferred embodiment of the present invention. As shown in FIG. 3a, the lens material layer 10 is smooth like a lens, wherein the lens material layer 10 is made of conductive material or non-conductive material, the non-conductive material is plastic or stone paper, and the plastic is polyimide and is configured to use as a film. The conductive material is stainless steel, for example, the conductive material is a foil, and a thickness of the foil is within 0.01 mm to 0.05 mm, wherein the stainless steel is smooth and is selected from 300 series stainless steel or 400 series stainless steel, for example, when the stainless steel is 300 series stainless steel, the 300 series stainless steel is any one of 304, 310, 316, and 321 series. When the stainless steel is 400 series stainless steel, the 400 series stainless steel is any one of 410, 420, and 430 series.

In another embodiment, the conductive contact layer 20 mates with the lens material layer 10 and the first n-p semiconductor layer 30, wherein the conductive contact layer 20 is made of conductive metal material or conductive non-metal material, and the conductive metal material is any one of molybdenum (Mo), carbon, and tin oxide.

In another embodiment, the first n-p semiconductor layer 30 is p-type semiconductor material made of copper indium gallium selenite (CIGS), and the conductive contact layer 20 is made of molybdenum (Mo).

In another embodiment, the first n-p semiconductor layer 30 is p-type semiconductor material made of cadmium telluride (CdTe), and the conductive contact layer 20 is made of carbon or tin oxide.

With reference to FIG. 3d, a respective first via 40 passes through the lens material layer 10, the conductive contact layer 20, and the first n-p semiconductor layer 30 in a laser drilling manner or a punching manner.

Referring to FIG. 3e, in this embodiment, the second n-p semiconductor layer 50 is stacked on a top of the first n-p semiconductor layer 30, the insulation layer 60 is stacked on a bottom of the lens material layer 10, and the respective first via 40 includes the multiple insulators 80 accommodated therein. In this embodiment, as shown in FIG. 3d, cadmium sulfide (CdS) is covered on the top of the first n-p semiconductor layer 30 and the bottom of the lens material layer 10 and is accommodated in the multiple first vias 40 in a chemical bath deposition (CBD) manner, such that a respective insulator 80 includes a respective one of multiple second vias 81, wherein the respective second via 81 passes through the second n-p semiconductor layer 50, the respective insulator 80, and the insulation layer 60. Since the second n-p semiconductor layer 50 is insulated, the insulation layer 60 and the respective insulator 80 are made of materials the same as a martial (such as cadmium sulfide, CdS) of the second n-p semiconductor layer 50, for example, cadmium sulfide (Cds) is covered on the insulation layer 60 and the respective insulator 80 in the chemical bath deposition (CBD) manner so as to form an insulating edge 61, as illustrated in FIG. 3e, hence the first n-p semiconductor layer 30, the conductive contact layer 20, and the lens material layer 10 are insulated by the insulating edge 61.

In another embodiment, as illustrated in FIG. 3f, at least one transparent conducting layer 70 is stacked on a top of the second n-p semiconductor layer 50, and the substrate 90 is stacked on a bottom of the insulation layer 60, wherein the respective insulator 80 includes a respective second via 81 in which a respective electrical conductor 73 is formed, and a top of the respective electrical conductor 73 is connected with a respective transparent conducting layer 70 of the at least one transparent conducting layer 70, a bottom of the respective electrical conductor 73 is connected with the substrate 90 so that the respective transparent conducting layer 70 is electrically connected with the substrate 90, and the respective electrical conductor 73 is insulated by ways of the respective insulator 80, the conductive contact layer 20, and the lens material layer 10.

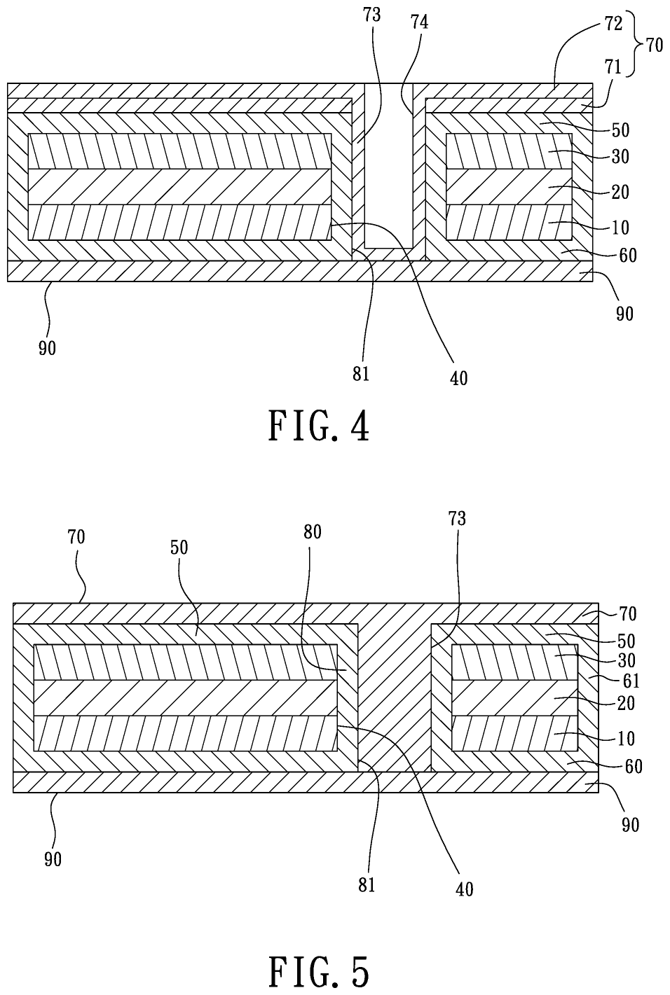

With reference to FIG. 4, in another embodiment, the transparent conducting layer 70 includes a first part 71 and a second part 72, wherein the first part 71 is stacked on the second n-p semiconductor layer 50 in a sputter deposition manner or an evaporation manner, the second part 72 is staked on the first part 71 in the chemical bath deposition (CBD) manner, and the respective electrical conductor 73 is formed in the respective second via 81, thus producing the respective electrical conductor 73 and the second part 72.

In another embodiment, a material of each of the first part, the second part 72, and the respective electrical conductor 73 is selected from any one of zinc oxide (ZnO), indium tin oxide (ITO), fluorine-doped tin oxide (FTO), antimony tin oxide (ATO), iridium tin oxide film (IRTOF), and tin oxide (SnO₂).

In another embodiment, the substrate 90 is made of conductive material, and the conductive material of the substrate 90 is metal or alloy material, wherein the metal of the conductive material of the substrate 90 is any one of aluminum, iron, copper, manganese, and stainless steel. The substrate 90 is stacked on the bottom of the insulation layer 60 by using adhesive, and the adhesive is sodium silicate (Na₂SiO₃).

A positive charge and a negative charge of the first n-p semiconductor layer 30 and the second n-p semiconductor layer 50 are collected by the transparent conducting layer 70 and the lens material layer 10 or by the transparent conducting layer 70 and the conductive contact layer 20, wherein the positive charge and the negative charge collected by the transparent conducting layer 70 is sent to the substrate via the respective electrical conductor 73, and the positive charge and the negative charge are outputted out of a first terminal 91 and a second terminal 92 from the substrate 90 and the lens material layer 10 (or the conductive contact layer 20) to supply electrical energy, as shown in FIG. 2A.

In this embodiment, the first n-p semiconductor layer 30 is p-type semiconductor material, and the second n-p semiconductor layer 50 is n-type semiconductor material.

In another embodiment, the first n-p semiconductor layer 30 is n-type semiconductor material, and the second n-p semiconductor layer 50 is the p-type semiconductor material.

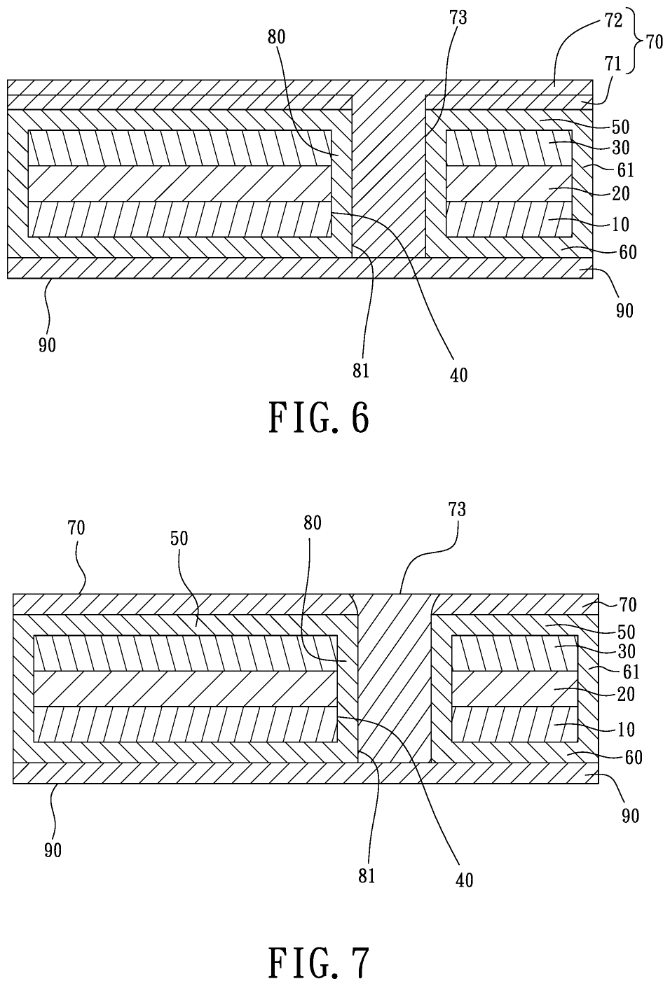

Referring to FIGS. 2A and 4, the respective electrical conductor 73 has a third via 74 and is solid. With reference to FIGS. 5 and 6, the third via 74 is filled completely in a chemical bath deposition (CBD) process, in other words, the third via 74 is solid and a top of the third via 74 is coplanar with the top of the respective electrical conductor 73. As shown in FIG. 7, in another embodiment, the transparent conducting layer 70 is stacked on the second n-p semiconductor layer 50 in a sputter deposition manner or in an evaporation manner, wherein the respective second via 81 extends to and passes through the transparent conducting layer 70, and the respective electrical conductor 73 is filled in the respective second via 81. In this embodiment, the respective electrical conductor 73 is made of material different from material of the transparent conducting layer 70, wherein the material of the respective electrical conductor 73 is conductive glue, and the conductive glue is silver glue. In addition, the material of the transparent conducting layer 70 is zinc oxide (ZnO).

While the preferred embodiments of the invention have been set forth for the purpose of disclosure, modifications of the disclosed embodiments of the invention as well as other embodiments thereof may occur to those skilled in the art. Accordingly, the appended claims are intended to cover all embodiments which do not depart from the spirit and scope of the invention.

What is claimed is:

1. A thin-film solar cell comprising:
a lens material layer;
a conductive contact layer stacked on the lens material layer;
a first n-p semiconductor layer stacked on the conductive contact layer;
a second n-p semiconductor layer stacked on a top of the first n-p semiconductor layer;
an insulation layer stacked on a bottom of the lens material layer;
a transparent conducting layer stacked on a top of the second n-p semiconductor layer;
a substrate stacked on a bottom of the insulation layer;
multiple first vias, and a respective of the multiple first via passing through the lens material layer, the conductive contact layer, and the first n-p semiconductor layer;
multiple insulators accommodated in the respective first via, wherein a top of a respective insulator is connected with the second n-p semiconductor layer, and a bottom of the respective insulator is connected with the insulation layer, wherein the respective insulator includes a respective of multiple second vias; and
multiple electrical conductors, wherein a respective electrical conductor is formed in the respective second via, a top of the respective electrical conductor is connected with a respective transparent conducting layer of at least one transparent conducting layer, and a bottom of the respective electrical conductor is connected with the substrate.

2. The thin-film solar cell as claimed in claim 1, wherein the transparent conducting layer includes a first part and a second part, the first part is stacked on the second n-p semiconductor layer in a sputter deposition manner or an evaporation manner, the second part is staked on the first part in a chemical bath deposition (CBD) manner, thus producing the respective electrical conductor.

3. The thin-film solar cell as claimed in claim 1, wherein the first n-p semiconductor layer is p-type semiconductor material made of copper indium gallium selenite (CIGS), and the conductive contact layer is made of molybdenum (Mo), wherein the second n-p semiconductor layer is n-type semiconductor material, and the n-type semiconductor material is cadmium sulfide (CdS).

4. The thin-film solar cell as claimed in claim 1, wherein the first n-p semiconductor layer is p-type semiconductor material made of cadmium telluride (CdTe), and the conductive contact layer is made of carbon or tin oxide, wherein the second n-p semiconductor layer is n-type semiconductor material, and the n-type semiconductor material is cadmium sulfide (CdS).

5. The thin-film solar cell as claimed in claim 1, wherein the insulation layer and the respective insulator are made of materials the same as a martial of the second n-p semiconductor layer.

6. The thin-film solar cell as claimed in claim 5, wherein the materials of the second n-p semiconductor layer, the respective insulator, and the insulation layer are cadmium sulfide (CdS).

7. The thin-film solar cell as claimed in claim 5, wherein the first n-p semiconductor layer, the conductive contact layer, and the lens material layer are insulated by an insulating edge.

8. The thin-film solar cell as claimed in claim 1, wherein the lens material layer is made of conductive material or non-conductive material.

9. The thin-film solar cell as claimed in claim 1, wherein the lens material layer is selected from any one of plastic, stone paper, and stainless steel.

10. The thin-film solar cell as claimed in claim 1, wherein the transparent conducting layer is made of a material selected from any one of zinc oxide (ZnO), indium tin oxide (ITO), fluorine-doped tin oxide (FTO), antimony tin oxide (ATO), iridium tin oxide film (IRTOF), and tin oxide (SnO₂).

11. The thin-film solar cell as claimed in claim 1, wherein a material of the transparent conducting layer is zinc oxide (ZnO), the respective second via extends to and passes through the transparent conducting layer, and the respective electrical conductor is filled in the respective second via, wherein the respective electrical conductor is silver glue.

12. The thin-film solar cell as claimed in claim 1, wherein the substrate is made of a material selected from any one of aluminum, iron, copper, manganese, and stainless steel.
